(19) United States
(12) Patent Application Publication
(10) Pub. No.: US 2014/0150847 A1
(43) Pub. Date: Jun. 5, 2014

(54) SOLAR CELL MODULE AND METHOD OF FABRICATING THE SAME

(71) Applicant: NATIONAL CHIAO TUNG UNIVERSITY, Hsinchu (TW)

(72) Inventors: Fang-Chung Chen, Hsinchu (TW); Chun-Hsien Chou, Hsinchu (TW); Jui-Kang Chuang, Hsinchu (TW); Yen-Tseng Lin, Hsinchu (TW)

(73) Assignee: National Chiao Tung University, Hsinchu (TW)

(21) Appl. No.: 13/757,011

(22) Filed: Feb. 1, 2013

(30) Foreign Application Priority Data
Nov. 30, 2012 (TW) 101144977

(51) Int. Cl. H01L 31/0232

(52) U.S. Cl. CPC H01L 31/02327; H01L 31/02322
USPC 136/247; 136/257; 438/65

(57) ABSTRACT

A solar cell module and a method of fabricating the same are provided. The method includes providing a solution having a luminescent dye, mixing the solution with a first waveguide material to obtain a first mixture, and placing the first mixture and a second mixture having nano-powder and a second waveguide material into a mold to form a waveguide body having a first layer body and a second layer body stacked on the first layer body. The waveguide body has a top surface, a bottom surface opposing to the top surface, and a lateral surface connecting the top surface with the bottom surface. At least one solar cell is disposed in the mold and embedded in the waveguide body, to enlarge a light reception area and light collection.

### BACKGROUND OF THE PRESENT INVENTION

1. Field of the Present Invention

This invention relates to solar cell modules and methods of fabricating the same, and more particularly, relates to a method of fabricating a solar cell module by a molding approach and a solar cell module that is integrally packaged.

2. Description of Related Art

Presently, solar cells (or photovoltaic cells) have high cost, and thus are not popular in daily lives. Generally, solar cells can be categorized into single crystalline silicon solar cells, concentrator solar cells, and thin-film solar cells.

The energy conversion efficiency of a single crystalline silicon solar cell has reached about 19 to 20%, and the energy conversion efficiency of the single crystalline silicon solar cell, after packaged, reduces to about 15 to 17%. A silicon solar cell module comprises glass, a single crystalline silicon solar cell, a packaging material (EVA, PVB, and the like) and an insulation material (PET, TPT and the like), and is packaged by a vacuum thermoforming method. Although a single crystalline silicon solar cell has the greatest yield and is more applicable in the market, its high price is still the major factor precluding it from becoming available in the daily life. In addition, since the cell chips of a silicon solar cell module are connected in series, the shadowing, if occurs, will decrease the efficiency. Therefore, it should be built at a spacious place without shadowing.

The concentrator solar cell mainly applies III-V group solar cells with a high magnification concentrator and a sun tracking system, in which the energy efficiency of the cell is about 24 to 28%. Although the concentrator solar cell has a high energy conversion efficiency, it uses III-V group elements, which are usually rare earth metals, such as Ga and In, as the material, the production cost is much higher than other solar cells. In order to make the generating capacity match the cost, tens of sets of concentrator solar cell module are usually used in one solar tracking system, and the whole construction cost is considerably expensive. Due to the requirement of the enormous holder installation module and the radius of rotation for the holder to follow a sun tracking system, the concentrator solar cell module system requires a spacious place. Further, the concentrator would lead to high temperature under high-magnification conditions, and it is also important to consider thermal dissipation design in the module. Moreover, in order to reach the highest efficiency of the concentrator solar cell module, a place with sufficient sunlight is necessary, and thus cloudy or weak sunlight would directly influence the generating capacity.

Thin-film solar cells can generally be categorized as compound solar cells, amorphous silicon solar cells, copper indium gallium selenium (CIGS) solar cells, and organic (polymer) solar cells. The main features are low price, light and thin, and flexible. Presently the highest energy efficiency of a thin-film solar cell module is 14.4% (CdTe, First Solar of United States). Although a thin-film solar cell features advantages such as low cost and flexibility, the biggest problem is their low energy efficiencies. In addition, since the production process of the CIGS solar cell is metal evaporation, it could not have a good deflection, and thus the application is limited.

In addition, due to the high cost and other conditions, the solar-energy-using luminescent solar concentrator (LSC) has been gradually noticed. Luminescent solar concentrator (LSC) was initially proposed by W. H. Weber and John Lambe in 1976. LSC mainly uses glass or transparent plastic material as the substrate and the waveguide. In LSCs, the difference in refraction indexes between the air and the waveguide results in total reflection. Further coatings or doping of luminescent dyes such as organic luminescent molecules and luminescent quantum dots converts the incident light through scattering to waveguiding mode. Moreover, the stoke's shift, which is resulted from the absorption and re-emission of the incident solar radiation, adjusts the wavelength, reducing the self-absorption efficiency during the propagation in the waveguide to the solar cell attached to the substrate edge. The advantages of LSCs include high transmittance and low cost. Further, because of the waveguide characteristics, no shadowing problem, which is concerned in a traditional solar cell, occurs in this type of solar module. Presently, the LSC proposed by L. H. Slooff and E. E. Bende of Energy Research Center of the Nederland (ECN) in 2008 has the highest energy conversion efficiency of 7.1%. However, since presently most developments are focusing on huge applications like building-integrated photovoltaic (BIPV) and smart energy saving window, rigid glass or transparent acrylic is mostly applied as the substrate. Those rigid materials will limit the applications of LSCs. In addition, the solar cell and the rigid substrate have to be adhered with each other by methods like optical clear adhesive or fixture embedment, which also increases the complexity and difficulty of the production.

U.S. Pat. No. 6,476,312B1 discloses that by using the characteristic of optical material waveguide, for example, the move of a concentrator congregates the light of quantum dots to the lateral side in a solar cell, wherein luminescent quantum is used as dyes and optical clear adhesive is used to the soar cell. However, the use of the optical clear adhesive to the solar cell in the post-production process would result in the complexity of production. U.S. Pat. No. 7,672,549B2 discloses the use of optical material waveguiding characteristics to control the path of light for deflecting the incident light into solar cells. However, the waveguide material is formed into different shapes or a reflect mirror is added to change the path of light, resulting in the complexity of production. U.S. Pat. No. 7,940,457B2 discloses using optical materials as the integration between windows and solar concentrator to produce smart energy saving windows. However, the disclosure of U.S. Pat. No. 7,940,457B2 is directed to a structure of smart energy saving windows and a fabrication method thereof without flexible waveguide components involved therein.

Therefore, the high material cost of solar cell modules, the shadowing issue, which will lead to lower efficiencies, the requirement of optical clear adhesive or fixture embedment for adhering rigid substrate to the solar cells, and complexity of the installation work all require additional production steps and cost.

Thus, there is a need to develop a solar cell module with decreased production complexity, low cost, more flexibility and higher collecting efficiency.

### SUMMARY OF THE PRESENT INVENTION

The present invention provides a solar cell module and a method for forming the same with increased light reception area and collecting efficiency.

The present invention provides a method of manufacturing a solar cell module, comprising the following steps of: (a) providing a solution having a luminescent dye; (b) mixing the solution with a first waveguide material to obtain a first mixture; and (c) placing the first mixture and a second mixture having nano-powder and a second waveguide material into a mold to form a waveguide body having a first layer body and a second layer body stacked on the first layer body, wherein the waveguide body has a top surface, a bottom surface opposing to the top surface, and a lateral surface connecting the top surface with the bottom surface, and at least a solar cell is disposed in the mold and embedded in the waveguide body.

The present invention further provides a solar cell module, comprising a waveguide body having a first layer body and a second layer body stacked on the first layer body, wherein the first layer body has a first waveguide material and a luminescent dye, the second layer body has a second waveguide material and nano-powder, and the waveguide body has a top surface, a bottom surface opposing to the top surface, and a lateral surface connecting the top surface with the bottom surface; and at least a solar cell embedded in the waveguide body.

In accordance with the present invention, a molding method is used form the solar cell module with one or more layers, which is a simple production process. In addition, when the waveguide body forms the panel, solar cell is embedded in the waveguide body so that the top surface and the bottom surface are the planes for light to pass into and scatter, and the light reception area and collecting efficiency are increased so as to reduce the number or the area of solar cells. In addition, sing highly flexible waveguide materials to form the desired size and appearance can resolve the heaviness and the complexity in the installation work for the solar cell module, wherein the installation work may be performed by arranging in order or rolling. On the other hand, the method of this invention can be repeated to obtain the solar cell module having a plurality of layers, and the luminescent dye and position can be controlled to increase the module efficiency.

### BRIEF DESCRIPTION OF DRAWINGS

The present invention can be more fully understood by reading the following detailed description of the preferred embodiments, with reference made to the accompanying drawings, wherein:

FIGS. 1A, 1B, and 1C are schematic diagrams of a solar cell module according to the present invention, wherein, FIG. 1B is a cross-sectional view of the solar cell module along a line A-A of FIG. 1B;

FIG. 2 shows a current-voltage characteristic of a solar cell module having a layer structure including mixed dyes under illumination in accordance with the embodiment 1 of the present invention;

FIG. 3 shows a current-voltage characteristic of a solar cell module having three luminescent layers under illumination in accordance with the embodiment 2 of the present invention;

FIG. 4 shows a current-voltage characteristic of a solar cell module without dyes under illumination in accordance with the comparative example 1 of the present invention; and

FIG. 5 shows a schematic diagram of the curvature of the mold and the corresponding module angles using in a test example.

### DETAILED DESCRIPTION OF THE PRESENT INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

In addition, “a first” and “a second” as described in this context are only used for the disclosure of this specification, provided for those in the art to understand and read, do not have substantial meaning technically.

The present invention provides a method of manufacturing a solar cell module, comprising the following steps of: (a) providing a solution having a luminescent dye; (b) mixing the solution with a first waveguide material to obtain a first mixture; and (c) placing the first mixture and a second mixture having nano-powder and a second waveguide material into a mold to form a waveguide body having a first layer body and a second layer body stacked on the first layer body, wherein the waveguide body has a top surface, a bottom surface opposing to the top surface, and a lateral surface connecting the top surface with the bottom surface, and at least a solar cell is disposed in the mold and embedded in the waveguide body.

Since the waveguide material is a colloid, if particles smaller than micrometers (um) are mixed with the waveguide material, an agglomeration is likely to occur. In the embodiment of the present invention, in order for the luminescent dye to be well mixed with the waveguide materials, a nontoxic volatile organic solvent is used as the solvent.

First, the luminescent dye is dissolved in an organic solvent according to a predetermined ratio to obtain the solution containing the luminescent dye, and the solution is mixed with the first waveguide material, then stirred and heated to evaporate the organic solvent, so to obtain the first mixture. On the other hand, the second mixture having the nano-powder mixed with the second waveguide material is prepared. The first mixture, the second mixture, and at least one preferred solar cell body are placed into a mold, and hardener is added to cure the first mixture and the second mixture into the first layer body and the second layer body, respectively, such that the solar cell is embedded in the waveguide body. Herein, the solar cell can be integrated in the interior of the waveguide body formed by a top surface, a bottom surface opposing the top surface, and a lateral surface. For example, the solar cell is upright in the wave-guide body with respect to the top surface or bottom surface.

In step (a), the luminescent dye is an organic luminescent dye or luminescent quantum dots. In addition, the luminescent dye can be dissolved in an organic solvent, such as alcohol (e.g., methanol or ethanol), ether (e.g., dimethyl ether or diethyl ether), or ketone (e.g., acetone).

In an embodiment, ethanol is used as the solvent dissolve the luminescent dye to obtain the solution containing the luminescent dye.

The first waveguide material and the second waveguide material are respectively selected from the group consisting of polymethylmethacrylate (PMMA), polyvinyl alcohol (PVA), polyvinyl pyrrolidone (PVP) and polydimethylsiloxane (PDMS). The first waveguide material and the second waveguide material can be the same or different.

Since having low clamor, high flexibility and high plasticity, polydimethylsiloxane is used as the waveguide material in embodiments of the present invention.

In one exemplary embodiment, the nano-powder is mixed with the second waveguide material to obtain the second mixture, and the nano-powder can be formed by TiO₂, BaSO₄, ZnS, nylon powder or metal oxide particles to scatter/reflect the incident light.

In an embodiment of forming a solar cell module, the first mixture is heated to remove the organic solvent. Specifically, the luminescent dye is first dissolved in ethanol to obtain the solution containing the luminescent dye, then the solution is dissolved in the waveguide material to obtain a first mixture, and the first mixture is placed on a heating plate to accelerate the on of ethanol.

In step (c), the first mixture and the second mixture are cured to become the first layer body and the second layer body, respectively, with a thermal curing agent or a light curing agent.

In an embodiment, the mold can be various shapes, such as (but not limited to) a circle, a polygon or a special polygon, to integrate the waveguide body to the solar cell. In an embodiment, the inner wall of the mold has a microstructure, and at least one of the top surface or the bottom surface of the waveguide body forms the corresponding light-guiding structure. The light-guiding structure or microstructure can crease the surface area and the curvature of the solar cell module, which is beneficial to increase the light reception area and the collecting efficiency so as to increase the incident light.

In an embodiment, step (c) comprises half-curing the first mixture and the second mixture so that at least one solar cell is embedded in the waveguide body, and shaping the waveguide body by reprocessing to obtain a desired shape. Specifically, since the soft waveguide material has plasticity, when a mixture containing waveguide material is in half-cured state, the pressing process can be performed to bend the shape, so that the waveguide material in half-cured state can be shaped as demands.

In an embodiment, the solar cell can be optionally selected, and it is not limited by the number of cells in use. In an embodiment of the present invention, a polysilicon solar cell is selected. In addition, in order to solve the problem that traditional solar cell placed at the center of the module may shadow the light, the solar cell may be placed on a lateral side of the module during the production. For example, the solar cell is fixed by taping, a mode, or vacuum adsorption, so that after forming the waveguide body the solar cell is embedded in the waveguide body.

In a embodiment of the present invention, step (a) to step(c) are repeated to obtain the solar cell module having a plurality of layers containing luminescent dyes. The waveguide materials in each of the layer structures are the same, the luminescent dyes may be the same or different, and there is no need to introduce the second mixture. Therefore, by controlling the color and position of luminescent dyes, the module can have a desired picture or text, and thus can be applied in various signs or advertising boards.

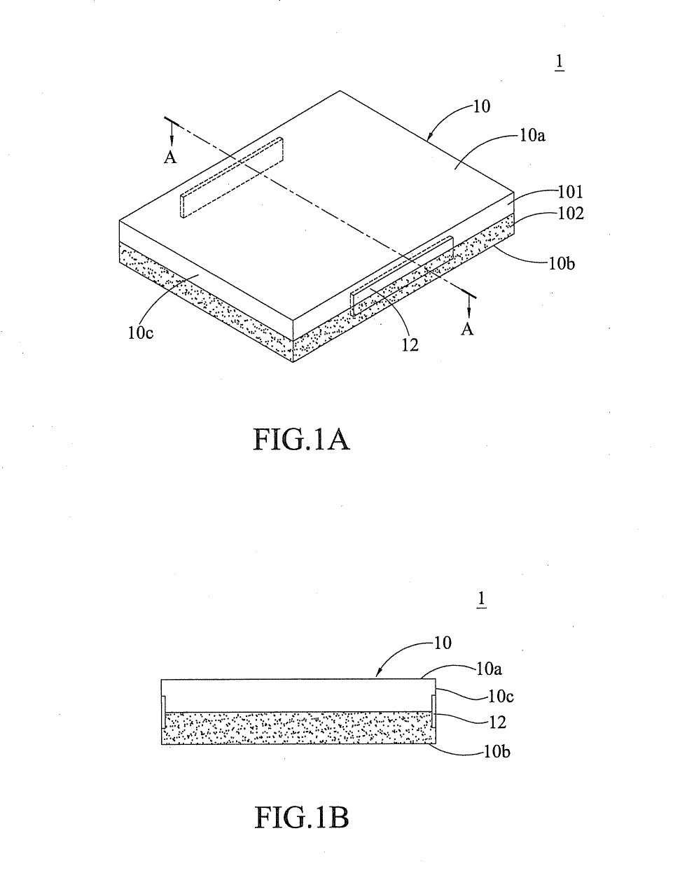

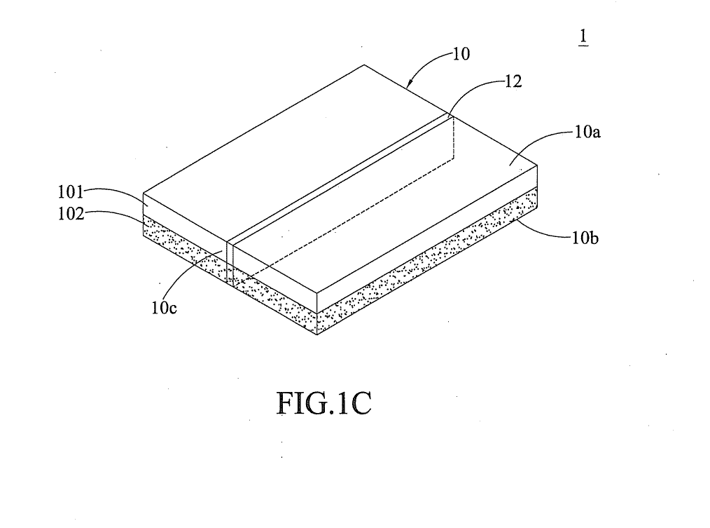

The present invention further provide a solar cell module. FIGS. 1A and 1B show perspective and sectional views of a solar cell module, wherein FIG. 1B is the sectional view of the solar cell module along the line A-A section in FIG. 1A. The solar cell module 1 comprises the waveguide body 10, which comprises the first layer body 101 containing the first waveguide material and the luminescent dye; and the second layer body 102 stacked on the first layer body 101 and containing the second waveguide material and the nano-powder. The waveguide body 10 has the top surface 10a, the bottom surface 10b opposing to the top surface 10a, and lateral surfaces 10c connecting the top surface 10a and the bottom surface 10b. Furthermore, at least one solar cell 12 is integrated on a lateral surface 10c of the waveguide body 10.

FIG. 1C is a perspective diagram of another solar cell module 1 according to the present invention. The solar cell module 1 comprises the waveguide body 10, which has the first layer body 101 containing the first waveguide material and the luminescent dye; and the second layer body 102 stacked on the first layer body 101 and containing the second waveguide material and the nano-powder. The waveguide body 10 has the top surface 10a, the bottom surface 10b opposing to the top surface 10a, and lateral surfaces 10c connecting the top surface 10a and the bottom surface 10b. Furthermore, at least one solar cell 12 is integrated at the center of the waveguide body 10.

The shape of waveguide body 10 may be, but not limited to a rectangle. Although the rectangle has 4 lateral surfaces 10c, the waveguide 10 is not limited to have 4 lateral surfaces. In addition, the position where the solar cell is embedded in the waveguide body is not limited. FIGS. 1A and 1B exemplarily illustrate that two solar cells 12 are placed on two opposite lateral surfaces 10c of the waveguide body 10, and FIG. 1C exemplarily illustrates that one solar cell 12 is placed at the center of the waveguide body.

On the other hand, the top surface and bottom surface named in this application are specified for convenience only. Usually, top surface and bottom surface mean the surfaces with larger area.

In an embodiment, the first waveguide material and the second waveguide material are respectively selected from the group consisting of polymethylmethacrylate (PMMA), polyvinyl alcohol (PVA), polyvinyl pyrrolidone (PVP) and polydimethylsiloxane (PDMS). The first waveguide material and the second waveguide material can be the same or different.

Also, the second waveguide material is mixed with the nano-powder to form the second mixture, which is cured to form the second layer body as a scattering layer or reflection layer, wherein the nano-powder is made of one selected from the group consisting of TiO₂, BaSO₄, ZnS, nylon powder and metal oxide particles.

In addition, usually, the second layer body containing nano-powder is located at an outer side of the waveguide body.

The following descriptions of the preferred embodiments are only illustrated to disclose the features and functions of the present invention and not restrictive to the scope of the present invention.

### Embodiment 1 Formation of a Solar Cell Module Having the First Layer Body and the Second Layer Body

According to the ratios shown in Table 1, the organic luminescent dye was dissolved in ethanol.

TABLE 1
Ratio for forming the solution having organic luminescent dye

| Organic luminescent | Organic luminescent | |
|---|---|---|
| dye solution | dye/Weight | Solution/Volume |
| Solution 1 | C545T/0.08 g | Ethanol/16 ml |
| Solution 2 | Rhodamine 640/0.001 g | Ethanol/5 ml |

C545T and Rhodamine 640 (purchased from Exciton)

Subsequently, according to the size of solar cell module (3×3×0.5 cm³), 4.5 ml of Polydimethylsiloxane (PDMS) was provided in a container, 0.3 ml of solution 1 and 0.2 ml of solution 2 were provided in the container to be mixed thoroughly. After solution 1, solution 2, and PDMS were well mixed, the container was placed on a heating plate at 90 to 120° C. to accelerate the volatilization of ethanol.

After the ethanol was completely volatilized, 0.45 ml of a thermal curing agent (purchased from Sil-More Industrial Ltd.) was provided into the PDMS mixture (volume ratio PDMS:curing agent=10:1) containing the organic luminescent dye. After well mixed, the mixture was placed in a vacuum chamber to remove bubbles. After the bubbles were removed, the PDMS mixture was poured into a mold with two silicon solar cell chip having area as 2×0.7 cm² placed at lateral sides, in which the bottom of the mold was flat, and the mold was placed on a heating plate at 100 to 120° C. to be heated and cured.

The TiO₂ powder (purchased from Ya Chung Industrial Co. Ltd.) was mixed with PDMS thoroughly (TiO₂:PDMS=0.2 g:1.8 ml), 0.18 ml of a thermal curing agent (volume ratio PDMS:curing agent=10:1) was added after the TiO₂ powder and PDMS were well mixed. After the PDMS containing the organic luminescent dye was heated and cured (about 15 to 20 minutes), the PDMS mixture containing TiO₂ was poured into the mold as a bottom scattering layer. PDMS mixture was heated until the PDMS mixture was completely cured, the mold was removed from the heating plate, the module was removed from the mold after being cool. The produced solar cell module has specific structure as shown in Table 2 below, wherein the first layer body and the second layer body are integrated to form a single layer structure.

TABLE 2

| | | | Second | |
|---|---|---|---|---|
| | First | First | layer body: | |
| | layer body: | layer | thickness of | |
| Module | luminescent dye | body: | bottom scat- | Number of |
| volume | layer structure | thickness | tering layer | solar cells |
| length × | Two organic | 0.5 cm | 0.2 cm | 2 chips of |
| width × | luminescent | | | polysilicon |
| height = | (C545T and Rho- | | | solar cell |
| 3 × 3 × | damine 640) mixed | | | |
| 0.7(cm³) | in single layer | | | |

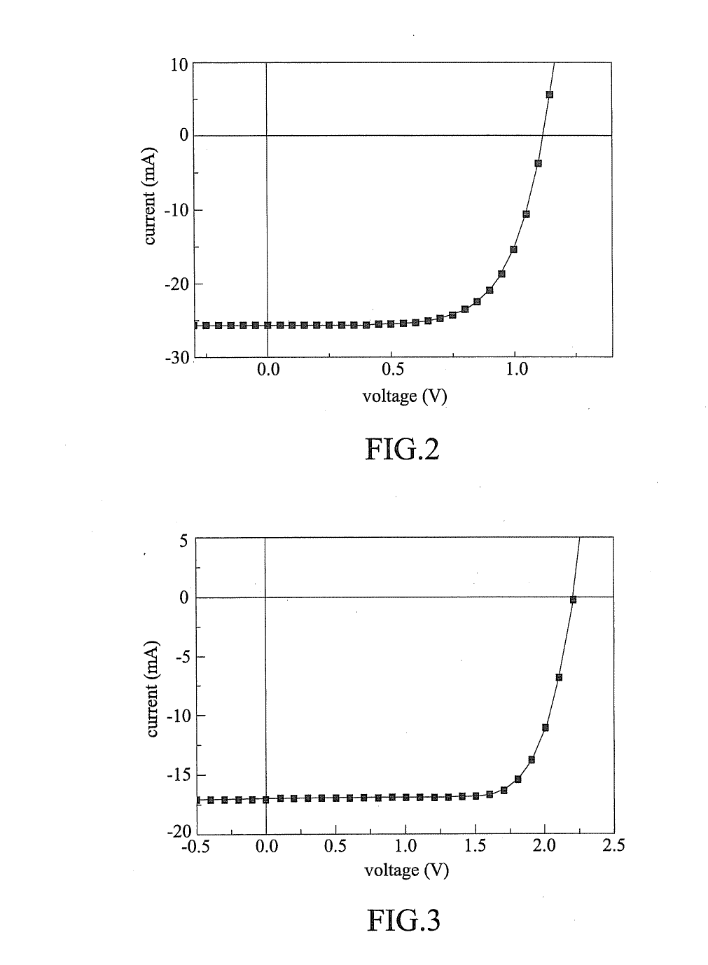

A sunlight simulator was applied to measure the short circuit current (I_{sc}), open circuit voltage (V_{oc}), fill factor, and energy transition efficiency (%) of the produced solar cell module. The measurement result is shown in Table 3. The current-voltage characteristic under illumination is shown in FIG. 2.

TABLE 3

| | | | | Power conversion |
|---|---|---|---|---|
| | Isc(mA) | Voc(V) | Fill factor | efficiency (%) |
| Measurement | −25.52 | 1.12 | 0.67 | 2.11 |
| result | | | | |

### Embodiment 2 Formation of a Solar Cell Module Having the First Layer Body and the Second Layer Body with 3 Luminescent Layers in Each Layer Body

According to the ratios shown in Table 4, the organic luminescent dye was dissolved in ethanol

TABLE 4
Ratio for producing organic luminescent dye solution

| | Organic luminescent dye/Weight | Solvent/Volume |
|---|---|---|
| Solution 3 | C545T/0.08 g | Ethanol/16 ml |
| Solution 4 | Rhodamine 640/0.001 g | Ethanol/5 ml |
| Solution 5 | Nile Blue/0.001 g | Ethanol/5 ml |

C545T, Sulforhodamine 640 solution, and Nile Blue (purchased from Exciton)

Subsequently, according to the ratios for each luminescent layer as shown in Table 5, the PDMS with a predetermined volume was absorbed for each luminescent layer and put into three respective containers. After the PDMS was well mixed with the solution, the containers were placed on heating plates at 90 to 120° C. to accelerate the volatilization of ethanol.

TABLE 5

| | First | Second | Third |
|---|---|---|---|
| | luminescent | luminescent | luminescent |
| | layer | layer | layer |
| Volume of organic | Solution 3/ | Solution 4/ | Solution 5/ |
| luminescent dye | 0.3 ml | 0.2 ml | 0.15 ml |
| solution | | | |
| Volume of PDMS | 1.35 ml | 1.8 ml | 1.35 ml |

After the ethanol was completely volatilized, 0.135 ml, 0.18 ml, and 0.135 ml of a thermal curing agent were put into those three containers, by referring to Embodiment 1. After well mixed, the mixtures was placed in the vacuum chamber to remove bubbles and obtain the first luminescent layer mixture, the second luminescent layer mixture, and the third luminescent layer mixture.

After the bubbles were removed, the first luminescent layer mixture was poured into a mold with silicon solar cell chips placed at four lateral sides, in which the bottom of the mold was flat and the mold was placed on a heating plate between 100 to 120° C. to be heated and cured, and the second luminescent layer mixture was poured after curing. In this way, the third luminescent layer mixture was poured to form stacked layers.

In addition, the TiO₂ powder was mixed with PDMS thoroughly (TiO₂:PDMS=0.2 g:1.8 ml), and 0.18 ml of thermal curing agent (volume ratio PDMS:curing agent=10:1) was added after the TiO₂ powder was well mixed with PDMS.

After the third luminescent layer mixture was cured (about 15 to 20 minutes), the PDMS mixture containing TiO₂ was poured into the mold as a bottom scattering layer. The PDMS mixture was heated continuously until it was cured completely, the mold was removed from the heating plate, and the module was removed from the mold after being cool. The produced solar cell module has the structure shown in Table 6, wherein the first, second, and third luminescent layers and the second layer body were described only for the convenience, and those are integrated to form a single layer structure.

TABLE 6

| | | Thickness | Second layer | |
|---|---|---|---|---|
| Volume | | of | body: thickness | |
| of | First layer body | Luminescent | of bottom | Number of |
| module | structure | dye layer | scattering layer | solar cells |
| length × | First lumi- | 0.15 cm | 0.2 cm | 4 chips of |
| width × | nescent layer | | | polysilicon |
| height = | (dye: C545T) | | | solar cell |
| 3 × 3 × | Second lumi- | 0.2 cm | | |
| 0.7(cm³) | nescent layer | | | |
| | (dye: sulforho- | | | |
| | damine 640) | | | |
| | Third lumi- | 0.15 cm | | |
| | nescent layer | | | |
| | (dye: Nile | | | |
| | Blue) | | | |

A sunlight simulator was applied to measure the short circuit current (I_{sc}), open circuit voltage (V_{oc}), fill factor, and energy transition efficiency (%) of the produced solar cell module. The measurement result is shown in Table 7 below. In addition, the current-voltage characteristic under illumination is shown in FIG. 3.

TABLE 7

| | | | | Power Conversion |
|---|---|---|---|---|
| | Isc(mA) | Voc(V) | Fill factor | efficiency (%) |
| Measurement | −16.97 | 2.2 | 0.74 | 3.1 |
| result | | | | |

### COMPARATIVE EXAMPLE 1

According to the size of module, a suitable amount of PDMS (3×3×0.5 cm³=4.5 ml) was provided into the container, and added with a curing agent by the ratio (PDMS:curing agent=10:1). After thoroughly mixed, the mixture was placed to be cool or placed in the vacuum chamber to remove bubbles

After the bubbles were removed, the PDMS mixture was poured into a mold with a silicon solar cell chip placed at the lateral side, in which the bottom of the mold was flat (which can also include microstructure patterns) and the mold was placed on a heating plate to be heated and cured (at 100 to 200° C.).

The TiO₂ powder and PDMS were mixed thoroughly (TiO₂:PDMS=0.15 g:0.9 ml), and 0.09 ml of a thermal curing agent was added by the ratio (volume ratio PDMS:curing agent=10:1) after the TiO₂ powder and the PDMS were well mixed.

After the PDMS in the mold was heated and cured (about 15 to 20 minutes), the PDMS mixture containing TiO₂ was poured into the mold as a bottom scattering layer. The PDMS mixture was heated continuously until it was cured completely, the mold was removed from the heating plate, and the module was removed from the mold after being cool.

In the module, the white reflect PET tapes (reflectivity larger than 95%) were adhered on the three lateral sides at which no solar cell was placed. The produced solar cell module had a single layer structure without luminescent dyes, and the structure was shown in Table 8 below.

TABLE 8

| | | Thickness | |
|---|---|---|---|
| | Thickness of | of bottom | Number of |
| Module volume | waveguide layer | scattering layer | solar cells |
| length × width × | 0.5 cm (without | 0.1 cm | 4 chips of |
| height = 3 × | luminescent | | polysilicon |
| 3 × 0.6(cm³) | materials) | | solar cell |

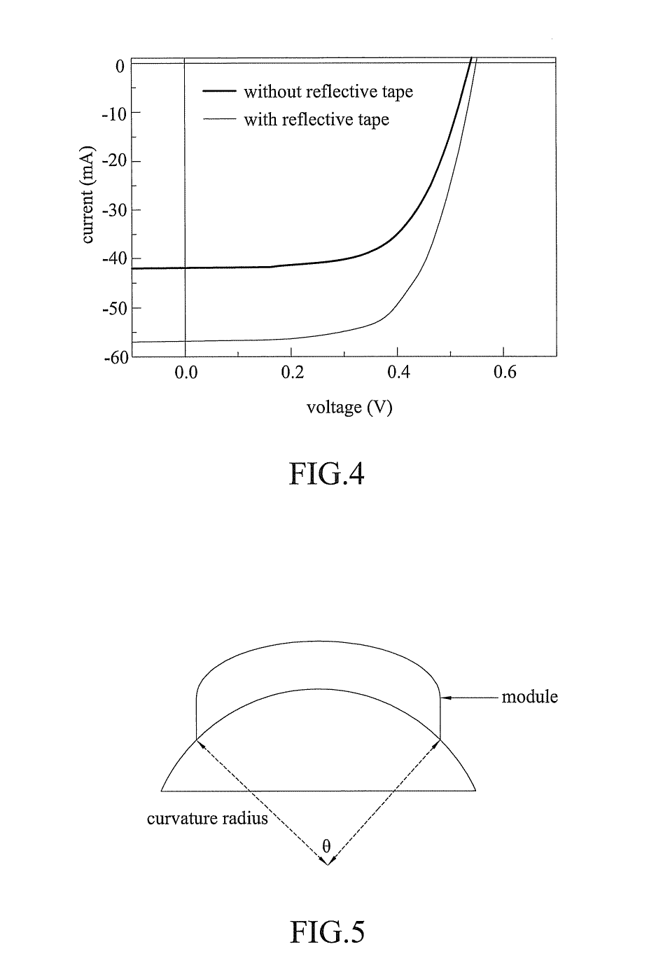

A sunlight simulator was applied to respectively measure the short circuit current (I_{sc}), open circuit voltage (V_{oc}), fill factor, and energy transition efficiency (%) of the solar cell module with or without white reflect PET tapes. The measurement result is shown in Table 9 below. In addition, the current-voltage characteristic under illumination is shown in FIG. 4.

TABLE 9

| | | | Fill | Power Conversion |
|---|---|---|---|---|
| Measurement result | Isc(mA) | Voc(V) | factor | efficiency (%) |
| Without reflective tape | −41.95 | 0.533 | 0.64 | 1.6 |
| With reflective tape | −56.96 | 0.545 | 0.64 | 2.2 |

### Flexibility Test

The flexibility test of the 3×3×0.7 cm³ solar cell module was performed with molds having different radiuses of curvature. The schematic diagram of the mold radius and the corresponding bending angle of the module are shown in FIG. 5, and the test result is shown in table 10 below.

TABLE 10

| | Mold radius of | Corresponding bending |
|---|---|---|
| Mold number | curvature (cm) | angle (θ) |
| 10 | 2.865312 | 59.989° |
| 20 | 1.987812 | 86.47° |
| 30 | 0.99005 | 173.61° |

After the test with the mold number 10, 20, and 30, it was known that the module of present invention had good flexibility, in particular bending over 180°. In addition, after bended more than 200 times the module was still intact or not deformed, which showed an advantageous recoverability.

In summary, by dissolving the luminescent dye into the nontoxic organic solvent, the waveguide material having good flexibility and plasticity is mixed with solution containing the luminescent dye thoroughly at low temperature and mixed with the nano-powder to be packed with the solar cell. In the present invention, production steps are simplified and production cost is lowered. In addition, the method of producing solar cell module in the present invention can not only form a big module but also a small one, for example, to be applicable to portable electronic devices, and thus has various applicability.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method of fabricating a solar cell module, comprising the steps of:
(a) providing a solution having a luminescent dye;
(b) mixing the solution with a first waveguide material to obtain a first mixture; and
(c) placing the)first mixture and a second mixture having nano-powder and a second waveguide material into a mold to form a waveguide body having a first layer body and a second layer body stacked on the first layer body, wherein the waveguide body has a top surface, a bottom surface opposing to the top surface, and a lateral surface connecting the top surface with the bottom surface, and at least a solar cell is disposed in the mold and embedded in the waveguide body.

2. The method of claim 1, wherein step (c) further comprises curing the first mixture and the second mixture to form the first layer body and the second layer body, respectively, with a thermal curing agent or a light curing agent, thereby forming the waveguide body.

3. The method of claim 1, wherein the luminescent dye is an organic luminescent dye or a luminescent quantum dot.

4. The method of claim 1, wherein the solution comprises an organic solvent, and the luminescent dye is dissolved in the organic solvent.

5. The method of claim 4, wherein the organic solvent is an alcohol, ether or ketone.

6. The method of claim 1, wherein the first waveguide material and the second waveguide material are respectively selected from the group consisting of polymethylmethacrylate (PMMA), polyvinyl alcohol (PVA), polyvinyl pyrrolidone (PVP) and polydimethylsiloxane (PDMS).

7. The method of claim 1, wherein step (c) comprises partially curing the first mixture and the second mixture, allowing the at least a solar cell to he embedded in the waveguide body; and shaping the waveguide body.

8. The method of claim 1, wherein the nano-powder is one selected from the group consisting of TiO₂, BaSO₄, ZnS, nylon powder and metal oxide particles.

9. The method of claim 1, wherein step (c) further comprises heating the first mixture to remove the organic solvent.

10. The method of claim 1, wherein the mold has a micro-structure disposed on an inner wall thereof, and a light-guiding structure corresponding to the micro-stricture is formed on at least one of the top surface and the bottom surface of the waveguide body.

11. A solar cell module, comprising:
a waveguide body having a first layer body and a second layer body stacked on the first layer body, wherein the first layer body has a first waveguide material and a luminescent dye, the second layer body has a second waveguide material and nano-powder, and the waveguide body has a top surface, a bottom surface opposing to the top surface, and a lateral surface connecting the top surface with the bottom surface; and
at least a solar cell embedded in the waveguide body.

12. The solar cell module of claim 11, wherein the luminescent dye is an organic luminescent dye or a luminescent quantum dot.

13. The solar cell module of claim 11, wherein the first waveguide material and the second waveguide material are respectively selected from the group consisting of polymethylmethacrylate (PMMA), polyvinyl alcohol (PVA), polyvinyl pyrrolidone (PVP) and polydimethylsiloxane (PDMS).

14. The solar cell module of claim 11, wherein the nano-powder is one selected from the group consisting of TiO₂, BaSO₄, ZnS, nylon powder and metal oxide particles.
